(19) United States
(12) Patent Application Publication
(10) Pub. No.: US 2025/0243061 A1
(43) Pub. Date: Jul. 31, 2025

(54) THIN FILM ASSEMBLY, AND SEMICONDUCTOR DEVICE, FIELD EFFECT TRANSISTOR AND IMAGE SENSOR INCLUDING THE SAME, AND METHOD OF MANUFACTURING THE SAME

(71) Applicant: Samsung Electronics Co., Ltd., Suwon-si (KR)

(72) Inventors: Jaewon KIM, Suwon-si (KR); Taehoon KIM, Suwon-si (KR); Hyeonjin SHIN, Suwon-si (KR); Van Luan NGUYEN, Suwon-si (KR); Taejin CHOI, Suwon-si (KR)

(73) Assignee: Samsung Electronics Co., Ltd., Suwon-si (KR)

(21) Appl. No.: 18/921,383

(22) Filed: Oct. 21, 2024

(30) Foreign Application Priority Data
Jan. 26, 2024 (KR) 10-2024-0012663

(51) Int. Cl. C01B 21/064; H01L 21/02; H01L 23/532; H01L 27/146; H01L 29/51

(52) U.S. Cl. CPC C01B 21/064; H01L 21/02175; H01L 21/02274; C01P 2006/40; H01L 23/5329; H10D 64/693; H10F 39/807

(57) ABSTRACT

A thin film assembly may include a boron nitride thin film layer including a boron nitride compound and an insertion layer having a dielectric constant of 4.0 or less, wherein the boron nitride thin film layer and the insertion layer may be alternately arranged one or more times.

### CROSS-REFERENCE TO RELATED APPLICATION

This application is based on and claims priority under 35 U.S.C. § 119 to Korean Patent Application No. 10-2024-0012663, filed on Jan. 26, 2024, in the Korean Intellectual Property Office, the disclosure of which is incorporated by reference herein in its entirety.

### BACKGROUND

### 1. Field

Provided are a thin film assembly including a boron nitride thin film layer; a semiconductor device, a field effect transistor and an image sensor, including the thin film assembly; and a method of manufacturing the thin film assembly.

### 2. Description of the Related Art

Integrated circuits of various electronic devices including display devices, image sensors, field effect transistors, memory devices, and the like may be manufactured by combining and connecting semiconductors, conductors, and insulators. For example, integrated circuits of various electronic devices may be manufactured by forming a plurality of unit devices on a substrate and then stacking interlayer insulating films and wirings thereon.

As the degree of integration of the integrated circuit increases, the distance between conductor patterns gradually decreases. Accordingly, parasitic capacitance between conductor patterns may increase, resulting in performance degradation of the electronic device. For example, parasitic capacitance may delay signal transmission of semiconductor devices. In order to reduce this parasitic capacitance, thin films with relatively low dielectric constants have been proposed as interlayer insulating films.

### SUMMARY

According to an embodiment, provided is a thin film assembly including a boron nitride thin film layer that maintains a low dielectric constant despite an increase in thickness.

According to an embodiment, provided is a method of manufacturing a thin film assembly including a boron nitride thin film layer.

According to an embodiment, provided are a semiconductor device, a field effect transistor, and an image sensor, each including a thin film assembly having a low dielectric constant.

Additional aspects will be set forth in part in the description which follows and, in part, will be apparent from the description, or may be learned by practice of the presented embodiments of the disclosure.

According to an embodiment, a thin film assembly may include a boron nitride thin film layer including a boron nitride compound and an insertion layer having a dielectric constant of about 4.0 or less, wherein the boron nitride thin film layer and the insertion layer may be alternately arranged one or more times.

In some embodiments, the boron nitride thin film layer may have a first thickness, the insertion layer may have a second thickness, and the second thickness may be less than or equal to the first thickness.

In some embodiments, a ratio of the first thickness to the second thickness may be 1 or more.

In some embodiments, the first thickness may be about 50 nm or less, and the second thickness may be about 50 nm or less.

In some embodiments, the insertion layer may include at least one of an organic material, an inorganic material, or an organic-inorganic hybrid material.

In some embodiments, the insertion layer may include phthalate esters (PAE), polyimide, parylene, polytetrafluoroethylene (PTFE), benzocyclobutene (BCB), polyvinylalcohol (PVA), polyacrylic acid (PAA), polyacrylamide (PAM), polyvinylpyridine (PVP), polymethyl methacrylate (PMMA), poly(styrenesulfonate) (PSS), poly(N-acryloyl piperidine) (PAP), covalent organic framework (COF), SiO₂, SiOF, SiCOH, nanoporous SiO₂, metal organic framework (MOF), and self-assembled monolayer (SAM).

In some embodiments, the insertion layer may be on an upper portion of the boron nitride thin film layer.

In some embodiments, a boron nitride cover layer may be on an upper portion of the insertion layer.

In some embodiments, the insertion layer may be on a lower portion of the boron nitride thin film layer.

In some embodiments, an insertion cover layer may be on an upper portion of the boron nitride thin film layer.

In some embodiments, the boron nitride thin film layer may have a dielectric constant of about 4 or less at an operating frequency of about 100 kHz.

In some embodiments, the boron nitride thin film layer may include at least one of an amorphous material and a nanocrystalline material.

According to an embodiment, a semiconductor device may include a substrate and a wiring structure on the substrate, wherein the wiring structure may include a dielectric layer, a conductive wiring, and a diffusion barrier layer, the diffusion barrier layer may include a thin film assembly. The thin film assembly may include a boron nitride thin film layer including a boron nitride compound; and an insertion layer having a dielectric constant of about 4.0 or less, and the boron nitride thin film layer and the insertion layer may be alternately arranged one or more times.

According to an embodiment, a field effect transistor may include a source, a drain, a channel between the source and the drain, a gate facing the channel, a gate insulating film between the gate and the channel, and spacers between the source and the gate and between the drain and the gate. The spacers each may include a thin film assembly. The thin film assembly may include a boron nitride thin film layer including a boron nitride compound and an insertion layer having a dielectric constant of about 4.0 or less, and the boron nitride thin film layer and the insertion layer may be alternately arranged one or more times.

According to an embodiment, an image sensor may include a substrate, a plurality of photodiodes on the substrate, a plurality of color filters corresponding to the plurality of photodiodes, and a thin film assembly provided the plurality of photodiodes and the plurality of color filters. The thin film assembly may include a boron nitride thin film layer including a boron nitride compound and an insertion layer having a dielectric constant of about 4.0 or less, and the boron nitride thin film layer and the insertion layer may be alternately arranged one or more times.

According to an embodiment, a method of manufacturing a thin film assembly may include preparing a substrate, growing a boron nitride thin film layer on the substrate using plasma from a reactive gas including a source for boron nitride at a temperature below about 700° C. or lower, and arranging an insertion layer with a dielectric constant of about 4.0 or less on an upper portion of the boron nitride thin film layer.

In some embodiments, the growing the boron nitride thin film layer and the arranging the insertion layer on the boron nitride thin film layer may be alternately and repeatedly performed two or more times.

In some embodiments, the arranging the insertion layer on the boron nitride thin film layer may be performed using one or more of spin coating, dip coating, spray coating, printing process, and a vapor deposition process.

In some embodiments, the boron nitride thin film layer may have a first thickness, the insertion layer may have a second thickness, and the second thickness may be less than or equal to the first thickness.

In some embodiments, the boron nitride thin film layer may have a dielectric constant of about 4 or less at an operating frequency of about 100 kHz.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic diagram of a thin film structure arranged on a substrate, according to an embodiment;

FIG. 2 is an enlarged schematic diagram of a thin film structure arranged on a substrate, according to an embodiment;

FIG. 3 is a scanning electron microscope (SEM) image of a thin film structure according to an embodiment;

FIG. 4 is a schematic diagram of a thin film structure arranged on a substrate, according to a comparative example;

FIG. 5 is a graph illustrating changes in dielectric constant according to changes in thickness of a thin film structure according to an embodiment;

FIG. 6 is a schematic diagram of a thin film structure arranged on a substrate, according to an embodiment;

FIGS. 7A and 7B are diagrams showing contact angles at the uppermost end of a thin film assembly according to an embodiment;

FIG. 8 is a schematic diagram of a thin film structure arranged on a substrate, according to an embodiment;

FIG. 9 is a schematic diagram of a thin film structure arranged on a substrate, according to an embodiment;

FIG. 10 is a schematic diagram of a thin film structure arranged on a substrate, according to an embodiment;

FIGS. 11 to 14 are reference diagrams illustrating a method of manufacturing a thin film structure according to an embodiment;

FIG. 15 is a cross-sectional view schematically illustrating a structure of an image sensor according to an embodiment;

FIG. 16 is a cross-sectional view schematically illustrating a structure of a semiconductor device including a wiring structure, according to an embodiment;

FIG. 17 is a cross-sectional view schematically showing the structure of a field effect transistor according to an embodiment;

FIG. 18 is a cross-sectional view schematically showing the structure of a field effect transistor according to an embodiment; and

FIG. 19 is a cross-sectional view schematically showing the structure of a vertical field effect transistor according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C”) may be construed as A only, B only, C only, or any combination of two or more of A, B, and C, such as, for instance, ABC, AB, BC, and AC.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%. The notion that elements are “substantially the same” may indicate that the element may be completely the same and may also indicate that the elements may be determined to be the same in consideration of errors or deviations occurring during a process.

The present inventive concept described below may apply various transforms and may have various embodiments, and specific embodiments are illustrated in the drawings and described in the detailed description in detail. However, this is not intended to limit the inventive concept to a specific embodiment, and it should be understood that the present inventive concept includes all transforms, equivalents, or replacements included in the technical scope of the inventive concept.

The terms used hereinafter are used only to describe particular embodiments, and are not intended to limit the present inventive concepts. Singular expressions include plural expressions unless the context clearly means otherwise. It will be further understood that the terms “comprise” or “have” used herein, specify the presence of stated features, numbers, steps, operations, elements, components, ingredients, materials, or combinations thereof, but do not preclude the presence or addition of one or more other features, numbers, steps, operations, elements, components, ingredients, materials, or combinations thereof.

In the drawings, the thickness is enlarged or reduced in order to clearly express various layers and regions. Like parts are denoted by the same reference numerals throughout the specification. It will be further understood that when a layer, a film, an area, a plate, or the like is referred to as being “on” or “over” another part throughout the specification, it is not only a case located directly on the other but also a case in which there is another part in the middle. Through the whole disclosure, the terms first, second, etc. may be used to describe various components, but the components should not be limited by terms. Terms are used only for the purpose of distinguishing one component from another.

In addition, hereinafter, embodiments will be described in detail with reference to the accompanying drawings. In the following drawings, the same reference numerals refer to the same components, and the size of each component in the drawings may be exaggerated for clarity and convenience of description. In addition, the embodiments described below are merely examples and various modifications are possible from these embodiments.

Hereinafter, the term “upper portion” or “on” may also include “to be present on a non-contact basis” as well as “to be in directly contact with”. The singular expression includes multiple expressions unless the context clearly implies otherwise. In addition, when a part “includes” a component, this means that it may further include other components, not excluding other components unless otherwise opposed.

The use of the term “the” and similar indicative terms may correspond to both singular and plural. If there is no explicit description of an order for steps that make up a method or vice versa, these steps can be done in an appropriate order and are not necessarily limited to the order described.

Further, the terms “unit”, “module” or the like mean a unit that processes at least one function or operation, which may be implemented in hardware or software or implemented in a combination of hardware and software.

The connection or connection members of lines between the components shown in the drawings as examples represent functional connection and/or physical or circuit connections, and may be replaceable or represented as various additional functional connections, physical connections, or circuit connections in an actual device.

The use of all examples or illustrative terms is simply to describe technical ideas in detail, and the scope is not limited due to these examples or illustrative terms unless the scope is limited by the claims.

In example embodiments, a thin film structure alternatively may be referred to a thin film assembly.

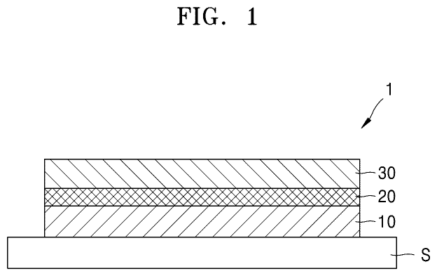

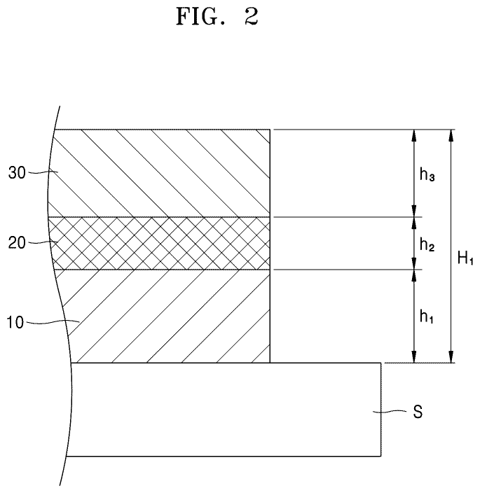

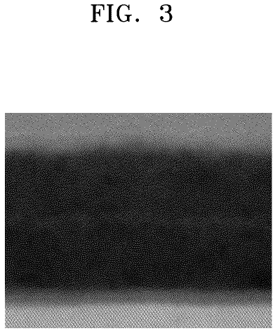

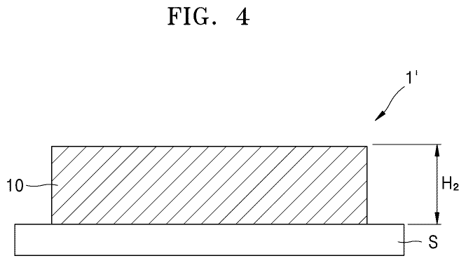

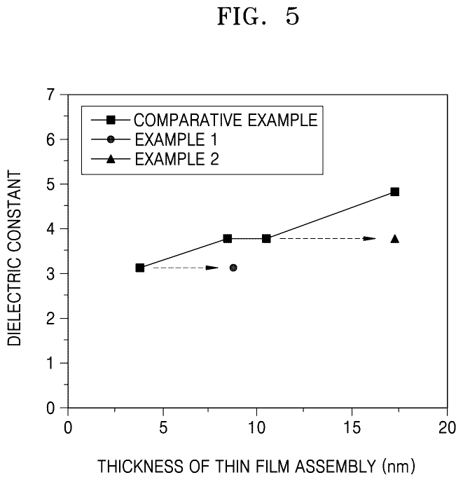

FIG. 1 is a schematic diagram of a thin film structure arranged on a substrate according to an embodiment. FIG. 2 is an enlarged schematic diagram of a thin film structure arranged on a substrate according to an embodiment. FIG. 3 is a scanning electron microscope (SEM) photograph of a thin film structure according to an embodiment. FIG. 4 is a schematic diagram of a thin film structure arranged on a substrate according to a comparative example. FIG. 5 is a graph illustrating a change in dielectric constant according to a change in thickness of a thin film structure according to an embodiment.

Referring to FIGS. 1 to 3, the thin film assembly 1 according to an embodiment may include a boron nitride thin film layer 10 and an insertion layer 20. In this case, the boron nitride thin film layer 10 and the insertion layer 20 may be alternately arranged on a substrate S once or more.

As an example, the boron nitride thin film layer 10 may include a boron nitride compound. The boron nitride thin film layer 10 according to an embodiment may include at least one of an amorphous material or a nanocrystalline material. For example, the boron nitride thin film layer 10 may be amorphous, and even if the boron nitride thin film layer 10 includes some crystals, it may include nano-sized crystals. In the process of manufacturing the boron nitride thin film layer 10 by depositing the boron nitride thin film layer 10 on the substrate S, when activated nitrogen and boron of low density are directly grown at low temperatures, the crystallinity of the boron nitride thin film layer 10 may be weak. In addition, as at least one of the temperature and process pressure is lower, the amorphous content of the boron nitride thin film layer 10 may increase.

The boron nitride thin film layer 10 according to an embodiment may have the same or substantially the same ratio of nitrogen and boron. The ratio of boron to nitrogen may be about 0.9 to about 1.1. In addition, the boron nitride thin film layer 10 may include hydrogen, but the hydrogen contained in the boron nitride thin film layer 10 may be in a small amount. For example, hydrogen included in the boron nitride thin film layer 10 may be about 10% or less. According to an embodiment, the boron nitride thin film layer 10 may be chemically stable because the hydrogen contained in the boron nitride thin film layer 10 may be in a small amount.

The boron nitride thin film layer 10 according to an embodiment may have a dielectric constant of about 4 or less (here, the dielectric constant may mean a relative dielectric constant for vacuum or air) at an operating frequency of about 100 kHz. For example, the amorphous boron nitride thin film layer (10; a-BN) may have a dielectric constant of about 2.3 or less at an operating frequency of about 100 kHz, and the nanocrystal boron nitride film (10; nc-BN) may have a dielectric constant of about 2.3 to about 2.5 at an operating frequency of about 100 kHz.

In addition, the mass density of the boron nitride thin film layer 10 according to an embodiment may vary depending on the dielectric constant of the boron nitride thin film layer 10. For example, the boron nitride thin film layer 10 according to an embodiment may have a mass density (g/cm²) of about 1 to about 3.

In addition, the breakdown field of the boron nitride thin film layer 10 according to an embodiment may be about 4 MVcm⁻¹ or more. In addition, the breakdown field of the boron nitride thin film layer 10 according to an embodiment may be about 5 to about 10 MVcm⁻¹.

The boron nitride thin film layer 10 according to an embodiment may have a smooth surface. For example, the surface of the boron nitride thin film layer 10 may have a root-mean-square (RMS) roughness value of about 0.3 to about 0.6.

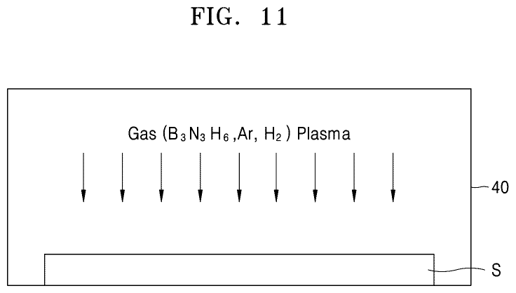

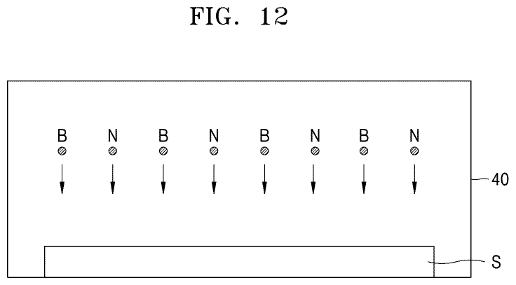

The boron nitride thin film layer 10 according to an embodiment may be manufactured through thin film growth according to vapor deposition of a compound consisting of boron and nitrogen atoms such as borazine. For example, the boron nitride thin film layer 10, which will be described later with reference to FIGS. 11 and 12, may be manufactured through thin film growth according to vapor deposition in which a compound consisting of boron and nitrogen atoms is deposited on the substrate S.

As the thickness of the boron nitride thin film layer 10 according to an embodiment increases, an energetically stable hexagonal crystalline material (e.g., an h-BN structure) may occur due to a metastable internal film stress. Accordingly, there may be a limit in which the dielectric constant of the boron nitride thin film layer 10 increases.

The crystallization of the boron nitride thin film layer 10, which may occur as the thickness of the boron nitride thin film layer 10 increases, is limited and/or suppressed, and a first thickness h₁ of the boron nitride thin film layer 10 may be limited to a desired and/or alternatively predetermined range so as to maintain amorphous characteristics. As an example, the boron nitride thin film layer 10 may have the first thickness h1 of about 50 nm or less. As the boron nitride thin film layer 10 has the first thickness h₁, the boron nitride thin film layer 10 may have a dielectric constant of about 4 or less at an operating frequency of about 100 kHz.

According to an embodiment, the insertion layer 20 may include a material having a dielectric constant of about 4.0 or less. For example, the insertion layer 20 may include at least one of an organic material, an inorganic material, and an organic-inorganic hybrid material having a dielectric constant of about 4.0 or less. For example, the insertion layer 20 may include phthalate esters (PAE), polyimide, parylene, polytetrafluoroethylene (PTFE), benzocyclobutene (BCB), polyvinylalcohol (PVA), polyacrylic acid (PAA), polyacrylamide (PAM), polyvinylpyridine (PVP), polymethyl methacrylate (PMMA), poly(styrenesulfonate) (PSS), poly(N-acryloyl piperidine) (PAP), covalent organic framework (COF), SiO₂, SiOF, SiCOH, nanoporous SiO₂, metal organic framework (MOF), and self-assembled monolayer (SAM).

According to an embodiment, the insertion layer 20 may have a thin film shape having a second thickness h₂. For example, the second thickness h₂ of the insertion layer 20 may be about 50 nm or less. In addition, according to an embodiment, the second thickness h₂ of the insertion layer 20 may include a thin film shape less than or equal to the first thickness h₁ of the boron nitride thin film layer 10. For example, a ratio of the first thickness h₁ of the boron nitride thin film layer 10 to the second thickness h₂ of the insertion layer 20 may be about 1 or more.

According to an embodiment, the insertion layer 20 and the boron nitride thin film layer 10 may be alternately arranged one or more times. As an example, when the boron nitride thin film layer 10 is arranged on the substrate S, the insertion layer 20 may be arranged on the boron nitride thin film layer 10. According to an embodiment, a boron nitride cover layer 30 may be arranged on the insertion layer 20. The boron nitride cover layer 30 according to an embodiment may have substantially the same characteristics as the boron nitride thin film layer 10, in the technical features except for a position in which the boron nitride cover layer 30 is arranged.

Referring to FIGS. 4 and 5, a thin film assembly 1′ including a boron nitride thin film layer 10 deposited on a silicon wafer substrate S is disclosed as a comparative example. In the boron nitride thin film layer 10 disclosed as a comparative example, a ratio of nitrogen to boron is about 0.8 to about 1.4. As a comparative example, the thickness H2 of the thin film assembly 1′ may be increased from about 3 nm to about 35 nm.

Referring to FIGS. 2 and 5, the thin film assembly 1 including the boron nitride thin film layer 10, the insertion layer 20, and the boron nitride cover layer 30 deposited on the silicon wafer substrate S is disclosed as Examples 1 and 2. The boron nitride thin film layer 10 and the boron nitride cover layer 30 disclosed in Examples 1 and 2 may have the same characteristics as the boron nitride thin film layer 10 disclosed in Comparative Example in the technical features except for the thickness. The insertion layer 20 may be a trifluoromethyl self-assembled monolayer (CF₃-SAM) having a thickness of about 1 nm.

In Example 1, the thickness h₁ of the boron nitride thin film layer 10 and the thickness h₃ of the boron nitride cover layer 30 are about 4 nm, and in Example 2, the thickness h₁ of the boron nitride thin film layer 10 and the thickness h₃ of the boron nitride cover layer 30 may be about 9 nm.

In Example 1, the thickness H₁ of the thin film assembly 1 including the boron nitride thin film layer 10, the insertion layer 20, and the boron nitride cover layer 30 may be about 9 nm. In this case, it may be confirmed that in Example 1, the dielectric constant is maintained at about 3. In addition, when the thickness H₂ of the thin film assembly 1′ of the comparative example increases to about 9 nm, it may be confirmed that the dielectric constant exceeds about 3.

In Example 2, the thickness H₁ of the thin film assembly 1 including the boron nitride thin film layer 10, the insertion layer 20, and the boron nitride cover layer 30 may be about 19 nm. In this case, it may be confirmed that in Example 2, the dielectric constant is maintained at less than about 4. In addition, when the thickness H₂ of the thin film assembly 1′ of the comparative example increases to about 19 nm it may be confirmed that the dielectric constant exceeds about 4.

As described above, as the insertion layer 20 is arranged between the boron nitride thin film layer 10 and the boron nitride cover layer 30, crystallization of the boron nitride thin film layer 10, which may occur as the thickness of the boron nitride thin film layer 10 increases, may be limited and/or suppressed. As crystallization of the boron nitride thin film layer 10 is limited and/or suppressed and amorphous characteristics are maintained, the thin film assembly 1 may have a low dielectric constant, for example, a dielectric constant of about 4 or less.

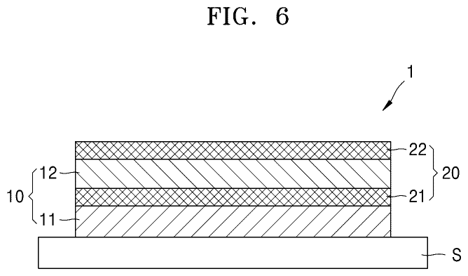

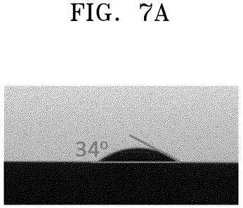

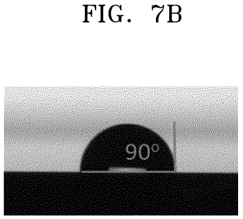

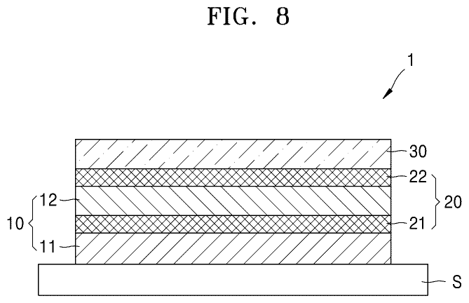

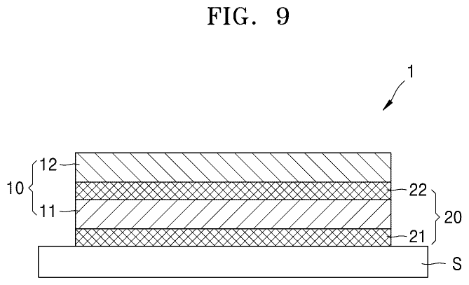

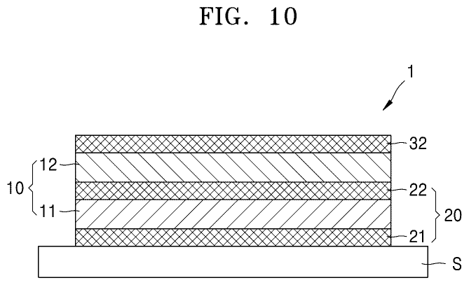

FIG. 6 is a schematic diagram of a thin film structure arranged on a substrate according to an embodiment. FIGS. 7A and 7B are diagrams showing contact angles at the uppermost end of a thin film assembly according to an embodiment. FIG. 8 is a schematic diagram of a thin film structure arranged on a substrate according to an embodiment. FIG. 9 is a schematic diagram of a thin film structure arranged on a substrate according to an embodiment. FIG. 10 is a schematic diagram of a thin film structure arranged on a substrate according to an embodiment.

Referring to FIGS. 6 to 10, the insertion layer 20 and the boron nitride thin film layer 10 according to an embodiment may be alternately arranged a plurality of times. For example, as shown in FIG. 6, when the first boron nitride thin film layer 11 is arranged on the substrate S, the first insertion layer 21 may be arranged on the first boron nitride thin film layer 11. In addition, the second boron nitride thin film layer 12 may be arranged on the first insertion layer 21. In addition, the second insertion layer 22 may be arranged on the second boron nitride thin film layer 12.

According to an embodiment, as shown in FIG. 8, a boron nitride cover layer 30 may be further arranged on an upper portion of the insertion layer 20 arranged at the uppermost end, for example, on the second insertion layer 22. The boron nitride cover layer 30 according to an embodiment may have substantially the same characteristics as the first and second boron nitride thin film layers 11 and 12, in the technical features except for a position in which the boron nitride cover layer 30 is arranged.

According to an embodiment, the insertion layer 20 or the boron nitride cover layer 30 may be selectively arranged at the uppermost end of the thin film assembly 1. Accordingly, the features of the uppermost end of the thin film assembly 1, for example, surface energy, etc., may be adjusted differently depending on the thin film layer to be placed.

As an example, when the boron nitride cover layer 30 is arranged at the uppermost end of the thin film assembly 1 as shown in FIG. 8, the contact angle at the uppermost end of the thin film assembly 1 may be about 34 degrees as shown in FIG. 7A. In addition, as shown in FIG. 6, when the second insertion layer 22 including the trifluoromethyl self-assembled monolayer (CF₃-SAM) is placed at the uppermost end of the thin film assembly 1, the contact angle at the uppermost end of the thin film assembly 1 may be about 90 degrees, as shown in FIG. 7B,

As described above, the boron nitride thin film layer 10 and the insertion layer 20 according to an embodiment may be alternately arranged. Therefore, as shown in FIGS. 9 and 10, the insertion layer 20 may be arranged under the boron nitride thin film layer 10. For example, as shown in FIG. 9, when the first insertion layer 21 is arranged on the substrate S, the first boron nitride thin film layer 11 may be arranged on the first insertion layer 21. In addition, the second insertion layer 22 may be arranged on the first boron nitride thin film layer 11. In addition, the second boron nitride thin film layer 12 may be arranged on the second insertion layer 22.

According to an embodiment, as shown in FIG. 10, an insertion cover layer 32 may be further arranged on the upper portion of the boron nitride thin film layer 10 arranged at the uppermost end, for example, on the upper portion of the second boron nitride thin film layer 12. The insertion cover layer 32 according to an embodiment may have substantially the same characteristics as the first and second insertion layers 21 and 22 in the technical features except for the position where the insertion cover layer 32 is arranged.

FIGS. 11 to 14 are reference diagrams illustrating a method of manufacturing a thin film structure according to an embodiment.

Referring to FIG. 11, a substrate S is prepared in a chamber 40. The substrate S may include at least one of a group IV semiconductor material, a semiconductor compound, an insulating material, and a metal. As a specific example, the substrate may include a group IV semiconductor material such as Si, Ge, or Sn. Alternatively, the substrate may include, for example, at least one of Si, Ge, C, Zn, Cd, Al, Ga, In, B, C, N, P, S, Se, As, Sb, and Te Ta, Ru, Rh, Ir, Co, Ta, Ti, W, Pt, Au, Ni, and Fe. In addition, the substrate may further include N and F as, for example, a SiCOH-based composition, and may include pores to reduce the dielectric constant. Meanwhile, the substrate S may further include a dopant. Materials of the substrate S mentioned above are merely examples.

The substrate S may be pretreated before the substrate S is arranged in the chamber 40. For example, the substrate S may be immersed in an organic solvent such as acetone for ultrasonic treatment, and then washed with iso-propenyl alcohol (IPA) and nitrogen gas. Carbon impurities remaining on the surface of the washed substrate S may be removed by performing plasma treatment such as oxygen hydrogen, NH₃, or the like. In addition, the substrate S may be immersed in an HF solution and natural oxides may be removed, or residual HF solution may be removed using anhydrous ethanol and N₂ gas.

The process temperature for growing the boron nitride thin film layer 10 may be approximately 700° C. or less, which is lower than the temperature used in the chemical vapor deposition process. For example, the process temperature inside the chamber 40 may be about 400° C. or in a range from about 400° C. to approximately 700° C. In addition, before raising the process temperature, the process pressure for growing the boron nitride thin film layer 10 may be set to approximately 2 Torr or less. For example, the process pressure may be about 10⁻² Torr or less.

Next, a reaction gas for growth of the boron nitride thin film layer 10 is injected into the chamber 40. Here, the reaction gas is a source for boron nitride for the growth of the boron nitride thin film layer 10, and may be a source including both nitrogen and boron, such as borazine (B₃N₃H₆) or ammonia-borane (NH₃—BH₃). Alternatively, the reaction gas may include a nitrogen source including nitrogen and a boron source including boron. The nitrogen source may include at least one of ammonia (NH₃) or nitrogen (N₂), and the boron source may include at least one of BH₃, BF₃, BCl₃, B₂H₆, (CH₃)₃B, and (CH₃CH₂)₃B.

The reaction gas may further include an inert gas. The inert gas may include, for example, at least one of argon gas, neon gas, nitrogen gas, helium gas, krypton gas, and xenon gas. The reaction gas may further include hydrogen gas. In addition, the mixing ratio of the reaction gas injected into the chamber 40 may be variously modified according to the growth condition of the boron nitride film.

The flow rate of the boron nitride gas may be lower than those of other reaction gases. When the boron nitride film is to be grown using plasma, the mixing ratio of the reactive gas injected into the chamber 40, that is, the volume ratio of the source for boron nitride and the inert gas may be, for example, about 1:about 10 to about 5000, or the volume ratio of the source for boron nitride and the inert gas and hydrogen gas may be, for example, about 1:about 10 to about 5000:about 10 to about 500.

The crystallinity of boron nitride is weakened because the content ratio of the source for boron nitride is small compared to other reaction gases. Thus, a boron nitride film according to an embodiment may be formed in an amorphous or nano-sized crystal structure.

When an excess of boron nitride source is supplied, the flow rate of the boron nitride source may be low because the boron nitride film may grow irregularly or the precursor may be adsorbed.

For example, while growing the boron nitride film, the flow rate of the source for boron nitride may be controlled to about 0.05 sccm (standard cubic centimeters), the flow rate of the inert gas may be controlled to about 50 sccm, and the flow rate of the hydrogen gas may be controlled to about 20 sccm. Although the flow controller 13 controls the flow rates of the source for boron nitride and the inert gas, embodiments are not limited thereto. The flow controller 13 may control only the flow rate of the source for boron nitride.

Subsequently, while a source for boron nitride flows into the chamber, a plasma device may generate plasma inside the chamber 40. Here, power for plasma generation may be about 10 W to about 4000 W. For example, the power for plasma generation is about 30 W, but embodiments are not limited thereto.

Referring to FIG. 12, activated nitrogen (N) and activated boron (B) may be generated by plasma of a reaction gas in which a carbon source, an inert gas, and a hydrogen gas are mixed and adsorbed on the surface of the substrate S. Additionally, the adsorption of activated nitrogen N and activated boron B on the surface of the substrate S may be accelerated by the plasma of the inert gas continuously inducing the activation of the substrate S. The activated nitrogen N and the activated boron B are adsorbed as the amorphous state. Even if activated nitrogen and boron are combined with each other, the amount is small and may be adsorbed into nano-sized crystals.

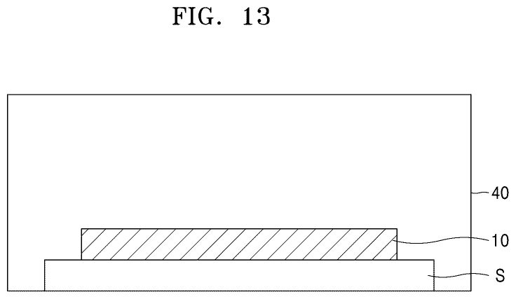

Referring to FIG. 13, a boron nitride thin film layer 10 may be grown on the surface of the substrate S as the adsorption of activated nitrogen (N) and activated boron (B) on the surface of the substrate S is accelerated even at low temperatures. According to this embodiment, the grown boron nitride thin film layer 10 may have weak crystallinity because the boron nitride thin film layer 10 is directly grown by a low ratio of activated nitrogen (N) and activated boron (B) on the surface of the substrate (S) at low temperatures, for example, about 700° C. or lower.

The boron nitride thin film layer 10 according to an embodiment may be grown to be amorphous or may be grown to be nitrided into nano-sized crystals. Even if there is a crystal in the amorphous boron nitride thin film layer 10, there may be crystals of about 3 nm or less, and the boron nitride thin film layer 10 formed of nanocrystals may include crystals of approximately 100 nm or less. More specifically, the boron nitride thin film layer 10 may include crystals each having a size of about 0.5 nm to about 100 nm. Accordingly, the boron nitride thin film layer 10 according to an embodiment may have a dielectric constant of about 4 or less at an operating frequency of about 100 kHz.

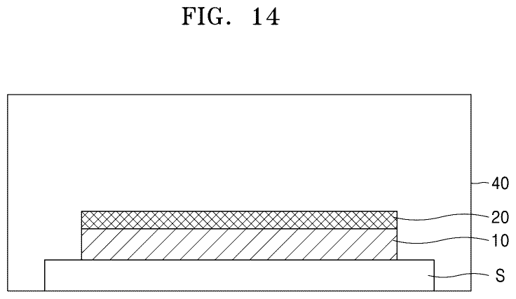

Referring to FIG. 14, the arranging of the insertion layer 20 having a dielectric constant of about 4.0 or less on the boron nitride thin film layer 10 may be formed by depositing a material having a dielectric constant of about 4.0 or less on the boron nitride thin film layer 10. As an example, the arranging of the insertion layer 20 on the boron nitride thin film layer 10 may be performed using one or more of spin coating, dip coating, spray coating, printing process, and vapor deposition process.

According to an embodiment, when a trifluoromethyl self-assembled monolayer (CF₃-SAM) is arranged on the boron nitride thin film layer 10, a CF₃-SAM saturated solution is used. It is also possible to prepare and utilize a CF₃-SAM solution by dissolving CF₃-SAM in water (H₂O) at room temperature.

A pretreatment process may be performed on the substrate S and the boron nitride thin film layer 10 before placing CF₃-SAM on the boron nitride thin film layer 10. The pretreatment process may be performed by an oxygen plasma process performed at about 2500 W power and a process pressure of about 1000 mtorr. The flow rate of oxygen gas is supplied at about 2500 sccm, the flow rate of nitrogen gas is supplied at about 250 sccm, and the pretreatment process may be performed at a process temperature of about 180° C. for about 90 seconds.

The CF₃-SAM solution may be coated on top of the boron nitride thin film layer 10. For example, the CF₃-SAM solution placed at a desired and/or alternatively predetermined interval, for example, spaced apart by about 5 cm, may be heated to a temperature of about 150° C. for about 3 hours to be vapor-deposited on the boron nitride thin film layer 10 and then cooled at room temperature.

The CF₃-SAM solution may be applied to the upper portion of the boron nitride thin film layer 10 using a spin coating method. For example, the boron nitride thin film layer (10) coated with the CF₃-SAM solution may be heated to a high temperature, for example, to a temperature of about 460° C. or less. When the boron nitride thin film layer 10 is heated, the CF₃-SAM and water (H₂O) may be separated from each other. Thereafter, the CF₃-SAM may be arranged on the upper portion of the boron nitride thin film layer 10 through a process of cooling the boron nitride thin film layer 10 to room temperature. According to an embodiment, the insertion layer 20 may be formed to be less than or equal to the thickness of the boron nitride thin film layer 10.

According to an embodiment, when the boron nitride thin film layer 10 and the insertion layer 20 are alternately arranged twice or more, the growing of the boron nitride thin film layer 10 and the arranging of the insertion layer 20 on the boron nitride thin film layer 10 may be repeated twice or more.

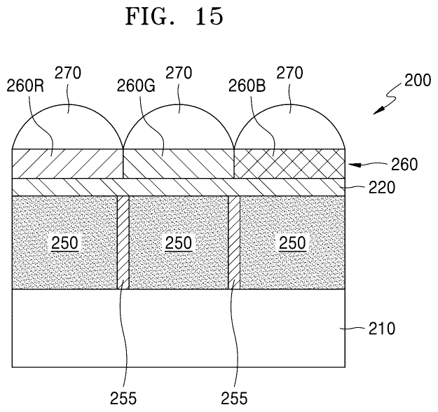

FIG. 15 is a cross-sectional view schematically illustrating a structure of an image sensor according to an embodiment.

Referring to FIG. 15, an image sensor 200 may include a substrate 210, a plurality of photodiodes 250 provided on the substrate 210, a thin film assembly 220 provided on the plurality of photodiodes 250, and a color filter layer 260 provided on the thin film assembly 220.

The plurality of photodiodes 250 may be arranged in a two-dimensional (2D) array form on the substrate 210. A black matrix 255 may be provided between two adjacent photodiodes 250. Each of the photodiodes 250 serves to convert incident light into electrical energy, and a metal wiring (not shown) for detecting electrical energy generated from each of the photodiodes 250 may be provided on the substrate 210.

The color filter layer 260 may include a plurality of color filters 260R, 260G, and 260B provided to correspond to the plurality of photodiodes 250. The plurality of color filters 260R, 260G, and 260B may include, for example, a red color filter 260R, a green color filter 260G, and a blue color filter 260B. However, embodiments are not limited thereto. A plurality of microlenses 270 corresponding to the plurality of color filters 260R, 260G, and 260B may be further provided in the color filter layer 260.

The thin film assembly 220 may be provided between the color filter layer 260 and the photodiodes 250. Here, the thin film assembly 220 serves to limit and/or prevent reflection of light incident through the color filter layer 260 and may have a low refractive index and a high hardness. Since the thin film assembly 220 has been described above, a description thereof is omitted. Since the thin film assembly 220 is applied as an anti-reflection film to the image sensor 200, the condensing of each pixel may be improved, and light interference that may occur between pixels may also be limited and/or prevented.

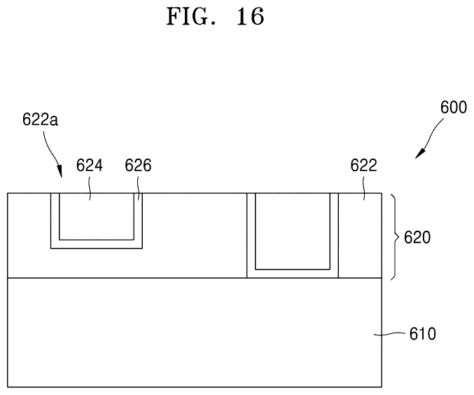

FIG. 16 is a cross-sectional view schematically illustrating a structure of a semiconductor device including a wiring structure according to an embodiment.

Referring to FIG. 16, a semiconductor device 600 may include a substrate 610 and a wiring structure 620 provided on the substrate 610. The wiring structure 620 may include a dielectric layer 622, a conductive wiring 624, and a diffusion barrier layer 626.

The substrate 610 may be a semiconductor substrate. For example, the substrate 610 may include a group IV semiconductor material, a group Ill-V compound semiconductor material, or a group II-VI compound semiconductor material. For example, the substrate 610 may include at least one semiconductor material from among Si, Ge, SiC, SiGe, SiGeC, Ge alloys, GaAs, InAs, and InP. This is merely an example, and other various semiconductor materials may be used as substrates. In addition, the substrate 610 may include a single layer or a plurality of layers in which different materials are stacked. For example, the substrate 610 may include a silicon-on-insulator (SOI) substrate or a silicon germanium-on-insulator (SGOI) substrate. Also, at least one semiconductor device (not shown) may be included in the substrate 610. The semiconductor device may include, for example, at least one of a transistor, a capacitor, a diode, and a resistor.

The dielectric layer 622 is formed on the substrate 610. The dielectric layer 622 may have a single layer structure or a multilayer structure in which different dielectric materials are stacked. The dielectric layer 622 may include a dielectric material used in a general semiconductor manufacturing process. For example, the dielectric layer 622 may include silicon oxide, silicon nitride, silicate, or the like. However, this is only an example, and other various dielectric materials may be used as the dielectric layer 622. In addition, the dielectric layer 622 may include a SiCOH-based organic/inorganic hybrid dielectric material. In addition, the dielectric layer 622 may include a thin film structure according to embodiments. When the dielectric layer 622 includes a thin film structure, a function of the diffusion barrier layer 626 to be described later may also be performed. In this case, the diffusion barrier layer 626 to be described later may be omitted.

At least one trench 622a may be formed in the dielectric layer 622 to have a desired and/or alternatively predetermined depth. Here, the at least one trench 622a may be formed not to contact the substrate 610 or may be formed to contact the substrate 610. In FIG. 16, two trenches 622a are formed in the dielectric layer 622, one trench 622a is formed not to contact the substrate 610, and the other trench 622a is formed to contact the substrate 610.

The conductive wire 624 is provided to fill the inside of the trench 622a. The conductive wiring 624 may include a metal or a metal alloy having excellent conductivity. For example, the conductive wiring 624 may include Cu, Ru, Al, Co, W, Mo, Ti, Ta, Ni, Pt, Cr, Rh, Ir, or an alloy thereof. However, embodiments are not limited thereto, and other various metals may be used as the conductive wiring 624.

A diffusion barrier layer 626 is formed on an inner wall of the trench 622a. Here, the diffusion barrier layer 626 may be provided to cover the conductive wiring 624 between the dielectric layer 622 and the conductive wiring 624. Specifically, the diffusion barrier layer 626 may be provided on the inner wall of the trench 622a to cover the side surface and the bottom surface of the conductive wire 624. The top surface of the conductive wiring 624 may be exposed by the diffusion barrier layer 626. The diffusion barrier layer 626 may serve to limit and/or prevent diffusion of a material forming the conductive wiring 624. Meanwhile, the diffusion barrier layer 626 may additionally serve as an adhesive layer between the dielectric layer 622 and the conductive wiring 624. The diffusion barrier layer 626 may include a thin film structure according to embodiments.

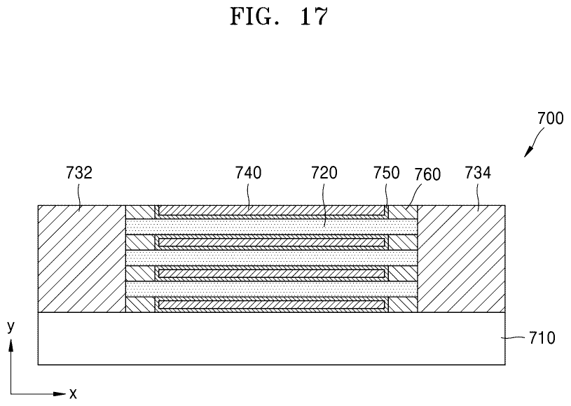

FIG. 17 is a cross-sectional view schematically showing the structure of a field effect transistor according to an embodiment.

Referring to FIG. 17, a field effect transistor 700 may include a substrate 710, a plurality of channels 720 arranged on the substrate 710, a source 732 and a drain 734 respectively in contact with both ends of each of the channels 720, and a plurality of gates 740 arranged to be spaced apart from the plurality of channels 720, respectively. The source 732 and the drain 734 may be spaced apart from each other in a first direction (e.g., an X direction), and the plurality of channels 720 may be spaced apart from each other in a second direction (e.g., a Y direction) between the source 732 and the drain 734.

The plurality of gates 740 are arranged to face the channels 720, respectively, and a gate insulating layer 750 may be arranged between the gate 740 and the channel 720. For example, the gate insulating film 750 may be provided to surround at least a portion of the gate 740. For example, the gates 740 and the channels 720 are alternately arranged in the second direction, and the gate insulating film 750 may surround each gate 740. The gate insulating film 750 may insulates between the channel 720 and the gate 740 and may limit and/or suppress leakage current.

A contact between each channel 720 and the source 732 and a contact between each channel 720 and the drain 734 may have an edge contact form. For example, each of both ends of each of the channels 720 may be in contact with the source 732 and the drain 734.

Each of the gates 740 is arranged to be spaced apart from the source 732 and the drain 734, and spacers 760 may be further arranged between the gate 740 and the source 732 and between the gate 740 and the drain 734, respectively. Since the source 732, the gates 740, and the drain 734 are arranged in the first direction, parasitic capacitance may occur between the source 732 and the gate 740 and between the gate 740 and the drain 734.

To reduce parasitic capacitance, each of the spacers 760 may include a thin film structure according to embodiments. Since the thin film structure according to embodiments has a relatively low dielectric constant of about 1.5 to about 4.0 at the about 100 kHz operating frequency, parasitic capacitance may be effectively reduced. In addition, since the thin film structure according to embodiments has excellent mechanical properties, the spacers 760 may support the channels 720 arranged thereon.

The field effect transistor 700 may have a multi-bridge type in which each of the plurality of channels 720 is in contact with the source 732 and the drain 734 at both ends thereof and is stacked to be spaced apart in a direction away from the substrate 710. Such a multi-bridge type channel may be advantageous for high integration because a short channel effect may be reduced and an area occupied by the source/drain may be reduced. In addition, the multi-bridge type channel may be applied as a high-speed and high-reliability device because uniform source/drain junction capacitance may be maintained regardless of the location of the channel.

The gate insulating layer 750 may include a dielectric material having a relatively high dielectric constant. The gate insulating film 750 may include, for example, aluminum oxide, hafnium oxide, zirconium hafnium oxide, lanthanum oxide, and the like. However, embodiments are not limited thereto. Alternatively, the gate insulating film 750 may include a ferroelectric material. When the gate insulating film 750 includes a ferroelectric material, the field effect transistor 700 may be applied as, for example, a logic device or a memory device. Alternatively, the gate insulating film 750 may have a multilayer structure including a high dielectric constant material and a ferroelectric material.

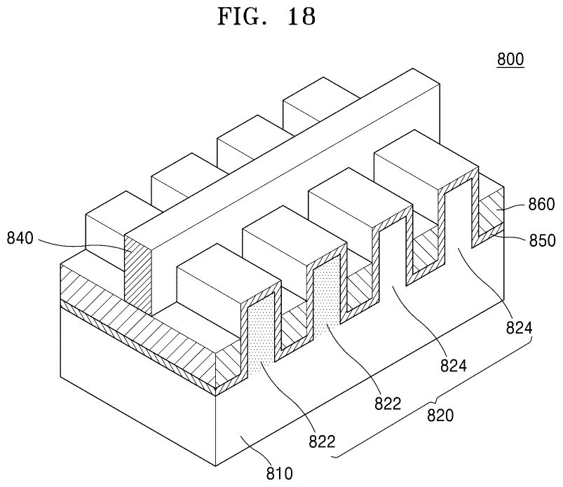

FIG. 18 is a cross-sectional view schematically showing the structure of a field effect transistor according to an embodiment.

Referring to FIG. 18, a field effect transistor 800 is a FinFET having a fin structure protruding from a substrate 810. The field effect transistor 800 may sufficiently secure the channel length because the protruding fin structures 822 and 824 may be used as the channel 820. Therefore, it is possible to limit and/or prevent or minimize the short channel effect, and to improve the occurrence of a leakage current and an area problem.

The field effect transistor 800 may include a substrate 810, an active fin 822, a dummy fin 824, a gate 840, a gate insulating film 850, and spacers 860. Although not shown in the drawings, both ends of the active fin 822 are electrically connected to the source and the drain, respectively. Although two active fins 822 are illustrated as channels, the number of active fins 822 is not limited thereto. The active fin 822 and the dummy fin 824 may be arranged to be connected to the substrate 810. In an embodiment, the active fin 822 may be an active region in which a portion protruding from the substrate 810 to the vertical portion is doped with n+ or p+, and the dummy fin 824 may be a region in which a portion protruding from the substrate 810 to the vertical portion is not doped. In another embodiment, both the active fin 822 and the dummy fin 824 may be active regions doped with n+ or p+. Each of the active fins 822 may have a width and a height, and the width and height of each of the active fins 822 may determine the width and height of each of the channels 820. The width and height of each of the channels 820 may be increased by the number of active fins 822.

The gate insulating film 850 may be arranged on the active fin 822 and the dummy fin 824. The gate insulating film 850 may include any one of an oxide film, a nitride film, and an oxynitride film.

Each of the spacers 860 may be arranged to have a desired and/or alternatively predetermined height in a space between the active fin 822 and the dummy fin 824. Each of the spacers 860 may include a thin film structure according to embodiments. Since each of the spacers 860 is arranged between the active fin 822 and the dummy fin 824, it is not only used as a device isolation film, but also parasitic capacitance may be reduced.

The gate 840 may be arranged above the gate insulating film 850 and the spacers 860. The gate 840 may have a structure surrounding the active fins 822, the dummy fins 824, and the spacers 860. In other words, the active fins 822 and the dummy fins 824 may have a structure arranged inside the gate 840.

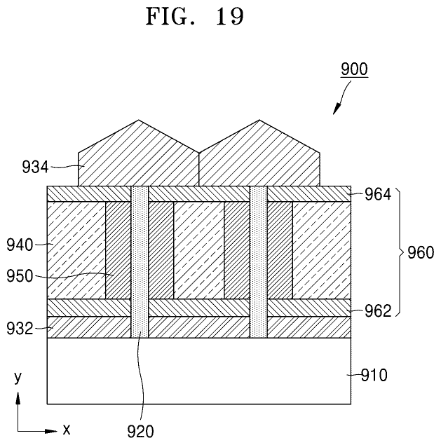

FIG. 19 is a cross-sectional view schematically showing the structure of a vertical field effect transistor according to an embodiment.

The field effect transistor 900 illustrated in FIG. 19 may be referred to as a vertical field effect transistor because current flows in a vertical direction through a channel 920 extending in the vertical direction from a substrate 910. The field effect transistor 900 of FIG. 19 may include the substrate 910, the channel 920, a source 932, a drain 934, a gate 940, a gate insulating layer 950, and a spacer 960.

The substrate 910 may include any of the materials describe above for the substrate 610 in FIG. 16.

The channels 920 may be spaced apart from each other in a first direction (e.g., an X-axis direction). The first direction may be parallel to the upper surface of the substrate 910. Each of the channels 920 may protrude from the upper surface of the substrate 910 in a second direction (e.g., a Y-axis direction). The second direction may be perpendicular to the top surface of the substrate 910. Forming the channel 920 may include forming a mask layer (not shown) on the substrate 910 and etching the substrate 610 using the mask layer as an etch mask to form the channel 920.

The source 932 may be disposed on substrate 910. The source 932 may surround a part of the channel 920 and may contact a lower region of the channel 920. The source 932 may be formed by performing an epitaxial growth process using the substrate 910 as a seed layer, and impurities may be added during the epitaxial growth process. However, the source 932 is not limited thereto. The source 932 may be formed by implanting impurities into the substrate 910. In addition, the source 932 may be disposed in contact with the side surface of the channel 920, but is not limited thereto, and may be disposed in contact with the lower surface of the channel 920.

The spacer 960 may include a first spacer 962 and a second spacer 964. The first spacer 962 may be disposed on the source 932, and the gate 940 and the gate insulating layer 950 may be disposed on the first spacer 962. The first spacer 962 may be provided to surround a part of the side surface of the channel 920, and the gate 940 may be disposed on the first spacer 962 while being spaced apart from the channel 920. The gate insulating layer 950 may be disposed on the first spacer 962 and between the gate 940 and the channel 920. The gate insulating layer 950 and the gate 940 may also extend vertically on the first spacer 962.

A second spacer 964 may be disposed on the gate 940 and the gate insulating layer 950, and the second spacer 964 may be provided to surround a part of the side surface of the channel 920.

In addition, a drain 934 may be formed on the channel 920. The drain 934 may be formed by the epitaxial growth process using the channel 920 as the seed layer. The drain 934 may be disposed to cover at least a part of the second spacer 964.

Each of the first and second spacers 962 and 964 may include a thin film structure (also referred to as thin film assembly) according to embodiments.

In FIG. 19, the source 932 is formed on the lower side of the channel 920, and the drain 934 is formed on the upper side of the channel 920, but the source 932 and the drain 934 are not limited thereto. The drain 934 may be formed on the lower side of the channel 920 and the source 932 may be formed on the upper side of the channel 920.

The semiconductor device, the field effect transistor, and the image sensor described above have been described with reference to the embodiments illustrated in the drawing.

According to an embodiment, a thin film assembly including a boron nitride thin film layer maintaining a low dielectric constant even with an increase in thickness may be provided.

According to an embodiment, a method of manufacturing a thin film assembly including a boron nitride thin film layer maintaining a low dielectric constant even with an increase in thickness may be provided.

According to an embodiment, a semiconductor device, a field effect transistor, and an image sensor, which each include a thin film assembly having a low dielectric constant may be provided.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A thin film assembly comprising:
a boron nitride thin film layer including a boron nitride compound; and
an insertion layer having a dielectric constant of 4.0 or less, wherein
the boron nitride thin film layer and the insertion layer are alternately arranged one or more times.

2. The thin film assembly of claim 1, wherein
the boron nitride thin film layer has a first thickness,
the insertion layer has a second thickness, and
the second thickness is less than or equal to the first thickness.

3. The thin film assembly of claim 2, wherein a ratio of the first thickness to the second thickness is 1 or more.

4. The thin film assembly of claim 2, wherein
the first thickness is 50 nm or less, and
the second thickness is 50 nm or less.

5. The thin film assembly of claim 1, wherein
the insertion layer comprises at least one of an organic material, an inorganic material, or an organic-inorganic hybrid material.

6. The thin film assembly of claim 5, wherein the insertion layer comprises one or more of phthalate esters (PAE), polyimide, parylenes, polytetrafluoroethylene (PTFE), benzocyclobutene (BCB), polyvinylalcohol (PVA), polyacrylic acid (PAA), polyacrylamide (PAM), polyvinylpyridine (PVP), polymethyl methacrylate (PMMA), poly(styrenesulfonate) (PSS), poly(N-acryloyl piperidine) (PAP), covalent organic framework (COF), SiO₂, SiOF, SiCOH, nanoporous SiO₂, metal-organic frameworks (MOFs), and self-assembled monolayers (SAMs).

7. The thin film assembly of claim 1, wherein the insertion layer is on an upper portion of the boron nitride thin film layer.

8. The thin film assembly of claim 7, further comprising:
a boron nitride cover layer on an upper portion of the insertion layer.

9. The thin film assembly of claim 1, wherein the insertion layer is on a lower portion of the boron nitride thin film layer.

10. The thin film assembly of claim 9, further comprising:
an insertion cover layer on an upper portion of the boron nitride thin film layer.

11. The thin film assembly of claim 1, wherein the boron nitride thin film layer has a dielectric constant of 4 or less at an operating frequency of 100 kHz.

12. The thin film assembly of claim 1, wherein the boron nitride thin film layer comprises at least one of an amorphous material and a nanocrystalline material.

13. A semiconductor device comprising:
a substrate; and
a wiring structure on the substrate, wherein
the wiring structure includes a dielectric layer, a conductive wiring, and a diffusion barrier layer,
the diffusion barrier layer includes the thin film assembly of claim 1.

14. A field effect transistor comprising:
a source;
a drain;
a channel between the source and the drain;
a gate facing the channel;
a gate insulating layer between the gate and the channel; and
spacers between the source and the gate and between the drain and the gate, wherein
the spacers each comprise the thin film assembly of claim 1.

15. An image sensor comprising:
a substrate;
a plurality of photodiodes on the substrate;
a plurality of color filters corresponding to the plurality of photodiodes; and
the thin film assembly of claim 1 between the plurality of photodiodes and the plurality of color filters.

16. A method of manufacturing a thin film assembly, the method comprising:
preparing a substrate;
growing a boron nitride thin film layer on the substrate using plasma from a reactive gas including a source for boron nitride at a temperature of 700° C. or lower; and
arranging an insertion layer with a dielectric constant of 4.0 or less on an upper portion of the boron nitride thin film layer.

17. The method of claim 16, wherein the growing the boron nitride thin film layer and the arranging the insertion layer on the boron nitride thin film layer are alternately and repeatedly performed two or more times.

18. The method of claim 16, wherein the arranging the insertion layer on the boron nitride thin film layer is performed using one or more of spin coating, dip coating, spray coating, a printing process, and a vapor deposition process.

19. The method of claim 16, wherein
the boron nitride thin film layer has a first thickness,
the insertion layer has a second thickness, and
the second thickness is less than or equal to the first thickness.

20. The method of claim 16, wherein the boron nitride thin film layer has a dielectric constant of 4 or less at an operating frequency of 100 kHz.
